(19) United States
(12) Patent Application Publication
(10) Pub. No.: US 2026/0074167 A1
(43) Pub. Date: Mar. 12, 2026

(54) CLEANING METHOD AND PLASMA PROCESSING APPARATUS

(71) Applicant: Tokyo Electron Limited, Tokyo (JP)

(72) Inventors: Tomonori SATO, Miyagi (JP); Hidetoshi HANAOKA, Miyagi (JP); Takanori MIMURA, Gyeonggi-do (KR); Atsumasa OMURO, Tainan City (TW); Yoichi NAKAHARA, Miyagi (JP); Futa MORITA, Miyagi (JP)

(21) Appl. No.: 19/391,046

(22) Filed: Nov. 17, 2025

Related U.S. Application Data
(63) Continuation of application No. PCT/JP2024/020091, filed on May 31, 2024.

(30) Foreign Application Priority Data
Jun. 1, 2023 (JP) 2023-090987

(51) Int. Cl. H01J 37/32

(52) U.S. Cl. CPC H01J 37/32862; H01J 37/32642; H01J 37/32807

(57) ABSTRACT

A cleaning method is provided, which is performed by a plasma processing apparatus including a plasma processing chamber and a support configured to support a part in the plasma processing chamber. The cleaning method includes: (A) removing the part from the support in the plasma processing chamber, and transferring the part out from the plasma processing chamber; (B) attaching a protective cover to a position corresponding to an attachment position of the part; and (C) generating a plasma from a cleaning gas, and cleaning an adhered substance adhered to the support by the plasma, wherein (A) is followed by (B), and (B) is followed by (C).

### CROSS-REFERENCE TO RELATED APPLICATIONS

This application is a continuation application of International Application No. PCT/JP2024/020091, filed on May 31, 2024, and designated the U.S., which is based upon and claims priority to Japanese Patent Application No. 2023-090987, filed on Jun. 1, 2023, the entire contents of which are incorporated herein by reference.

### BACKGROUND

### 1. Field of the Invention

The present disclosure relates to a cleaning method and a plasma processing apparatus.

### 2. Description of the Related Art

For example, Japanese Laid-Open Patent Application Publication No. 2018-010992 proposes transferring a focus ring from a processing chamber by a transfer device, and then cleaning a surface of a stage on which the focus ring was placed.

International Publication No. WO2022/250014 proposes, after dry cleaning of a processing chamber, transferring an edge ring out from the processing chamber by a transfer mechanism; and then, after cleaning of a stage by a suction mechanism, transferring an edge ring for replacement into the processing chamber.

U.S. Patent Application Publication No. 2009/0139540 proposes, after substrate processing, removing a part having the residue adhered thereto from a processing chamber; and then cleaning the removed part in a cleaning chamber.

Japanese Laid-Open Patent Application Publication No. 2021-141308 proposes raising an edge ring from a stage to dispose the edge ring at a first position or disposing a jig having the same shape as that of an edge ring at a first position, thereby performing cleaning.

### SUMMARY

According to one aspect of the present disclosure, a cleaning method performed by a plasma processing apparatus including a plasma processing chamber and a support configured to support a part in the plasma processing chamber is provided. The cleaning method includes: (A) removing the part from the support in the plasma processing chamber, and transferring the part out from the plasma processing chamber; (B) attaching a protective cover to a position corresponding to an attachment position of the part; and (C) generating a plasma from a cleaning gas, and cleaning an adhered substance adhered to the support by the plasma. (A) is followed by (B), and (B) is followed by (C).

### BRIEF DESCRIPTION OF THE DRAWINGS

FIG. 1 is a diagram illustrating an example of a plasma processing system according to one embodiment.

FIG. 2 is a flowchart illustrating a plasma processing method including a cleaning method according to one embodiment.

FIG. 3A is a diagram for describing Example 1 of the plasma processing method of FIG. 2.

FIG. 3B is a diagram for describing Example 1 of the plasma processing method of FIG. 2.

FIG. 3C is a diagram for describing Example 1 of the plasma processing method of FIG. 2.

FIG. 3D is a diagram for describing Example 1 of the plasma processing method of FIG. 2.

FIG. 4A is a diagram for describing Example 2 of the plasma processing method of FIG. 2.

FIG. 4B is a diagram for describing Example 2 of the plasma processing method of FIG. 2.

FIG. 4C is a diagram for describing Example 2 of the plasma processing method of FIG. 2.

FIG. 5A is a diagram for describing Example 2 of the plasma processing method of FIG. 2.

FIG. 5B is a diagram for describing Example 2 of the plasma processing method of FIG. 2.

FIG. 5C is a diagram for describing Example 2 of the plasma processing method of FIG. 2.

### DETAILED DESCRIPTION OF THE DISCLOSURE

The present disclosure provides a technique of enabling enhancing cleaning efficiency of a part in a chamber.

Hereinafter, embodiments of the present disclosure will be described with reference to the drawings. In the drawings, the same components are denoted by the same reference signs, and redundant description thereof may be omitted.

### [Plasma Processing System]

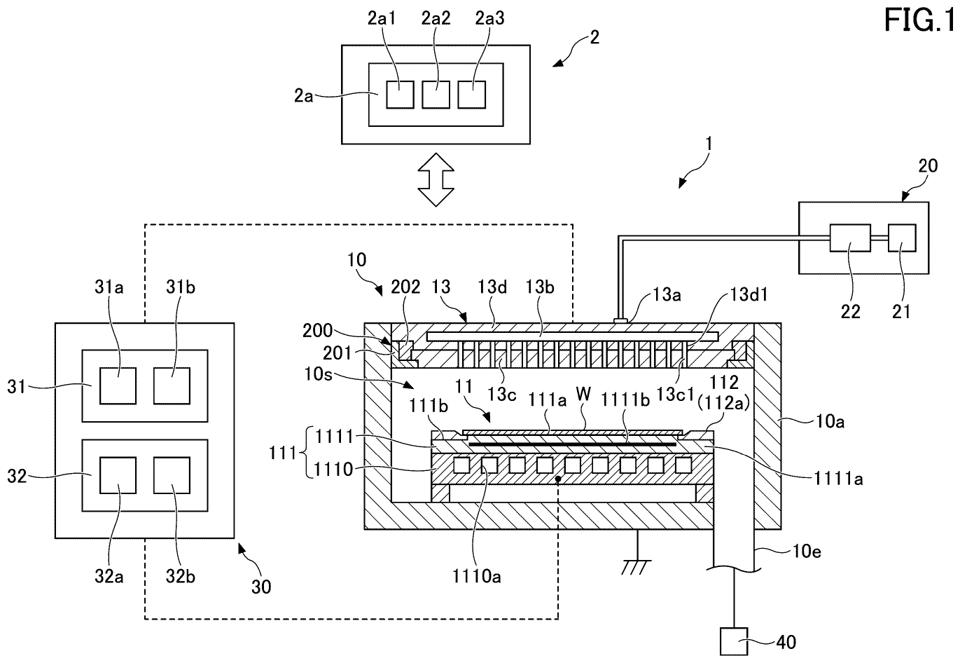

In the following, a configuration example of a plasma processing system will be described. FIG. 1 is a diagram for describing a configuration example of a capacitively coupled plasma processing apparatus.

The plasma processing system includes a capacitively coupled plasma processing apparatus 1 and a controller 2. The capacitively coupled plasma processing apparatus 1 includes a plasma processing chamber 10, a gas supply 20, a power supply 30, and a gas exhaust system 40. Also, the plasma processing apparatus 1 includes a substrate support 11 and a gas introducer. The gas introducer is configured to introduce at least one processing gas into the plasma processing chamber 10. The gas introducer includes a shower head 13. The substrate support 11 is disposed in the plasma processing chamber 10. The shower head 13 is disposed above the substrate support 11. In one embodiment, the shower head 13 forms at least a portion of a ceiling of the plasma processing chamber 10. The plasma processing chamber 10 includes a plasma processing space 10s that is defined by the shower head 13, a side wall 10a of the plasma processing chamber 10, and the substrate support 11. The plasma processing chamber 10 includes at least one gas supply port for supplying at least one processing gas to the plasma processing space 10s, and at least one gas discharge port for discharging a gas from the plasma processing space 10s. The plasma processing chamber 10 is grounded. The shower head 13 and the substrate support 11 are electrically insulated from a housing of the plasma processing chamber 10.

The substrate support 11 includes a body 111 and a ring assembly 112. The body 111 includes a central region for supporting a substrate W and an annular region for supporting the ring assembly 112. The central region is also referred to as a substrate support surface 111a for supporting the substrate W, and the annular region is also referred to as a ring support surface 111b for supporting the ring assembly 112. A wafer is an example of the substrate W. The ring support surface 111b of the body 111 encloses the substrate support surface 111a of the body 111 in a plan view. The substrate W is disposed on the substrate support surface 111a of the body 111. The ring assembly 112 is disposed on the ring support surface 111b of the body 111 to enclose the substrate W on the substrate support surface 111a of the body 111.

In one embodiment, the body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a includes the substrate support surface 111a. In one embodiment, the ceramic member 1111a also includes the ring support surface 111b. Note that other members enclosing the electrostatic chuck 1111, such as an annular electrostatic chuck or an annular insulating member, may include the ring support surface 111b. In this case, the ring assembly 112 may be disposed on the annular electrostatic chuck or the annular insulating member, or may be disposed on both the electrostatic chuck 1111 and the annular insulating member. Also, at least one RF (Radio Frequency)/DC (Direct Current) electrode coupled to an RF power supply 31 and/or a DC power supply 32, which will be described below, may be disposed in the ceramic member 1111a. In this case, the at least one RF/DC electrode functions as a lower electrode. When a bias RF signal and/or a DC signal, which will be described below, are supplied to the at least one RF/DC electrode, the RF/DC electrode is also referred to as a bias electrode. Note that the conductive member of the base 1110 and the at least one RF/DC electrode may function as a plurality of lower electrodes. Also, the electrostatic electrode 1111b may function as a lower electrode. Therefore, the substrate support 11 includes at least one lower electrode.

The ring assembly 112 includes one or more annular members. In one embodiment, the one or more annular members include one or more edge rings 112a and at least one cover ring. The edge ring 112a is formed of a conductive or insulating material, and the cover ring is formed of an insulating material.

Also, the substrate support 11 may include a temperature control module configured to adjust at least one of the electrostatic chuck 1111, the ring assembly 112, or the substrate to a target temperature. The temperature control module may include a heater, a heat transfer medium, a flow path 1110a, or any combination thereof. A heat transfer fluid, such as brine or gas, flows through the flow path 1110a. In one embodiment, the flow path 1110a is formed in the base 1110, and one or more heaters are disposed in the ceramic member 1111a of the electrostatic chuck 1111. Also, the substrate support 11 may include a heat transfer gas supply configured to supply a heat transfer gas to a gap between the rear surface of the substrate W and the substrate support surface 111a.

The shower head 13 includes an upper plate 13c and an upper support 13d. The upper plate 13c is disk-shaped, and a plurality of gas introducing holes 13c1 penetrate through the upper plate 13c in the thickness direction. The upper plate 13c is formed, for example, of silicon. The upper support 13d is fixed to the plasma processing chamber 10, and configured to support the upper plate 13c. The upper support 13d is disk-shaped, and includes a gas diffusion chamber 13b and a plurality of gas channels 13d1 communicating with the gas diffusion chamber 13b. The upper support 13d is formed, for example, of a metal, such as aluminum or the like.

The upper plate 13c is supported by the upper support 13d using a fixture 200 disposed on the outer circumference of the upper plate 13c. The fixture 200 includes a fixing portion 201 and a fastening portion 202. The fixing portion 201 is an annular member having a cross section in an L shape, and is provided on the inner wall surface of the side wall 10a of the plasma processing chamber 10. The fastening portion 202 is provided at a stepped portion of the fixing portion 201. The fastening portion 202 is configured to cause the upper plate 13c to be supported by the upper support 13d by screwing or the like the upper plate 13c to the upper support 13d with screws (not shown). However, a fixing method of the upper plate 13c is not limited to screwing.

The shower head 13 is configured to introduce at least one processing gas from the gas supply 20 into the plasma processing space 10s. The shower head 13 includes at least one gas supply port 13a, the at least one gas diffusion chamber 13b, and the plurality of gas introducing holes 13c1. The processing gas supplied to the gas supply port 13a passes through the gas diffusion chamber 13b, and is introduced into the plasma processing space 10s through the plurality of gas introducing holes 13c1. Also, the shower head 13 includes at least one upper electrode. The upper support 13d may function as an upper electrode. Note that the gas introducer may include, in addition to the shower head 13, one or more side gas injectors (SGIs) that are attached to one or more openings formed in the side wall 10a.

The gas supply 20 may include at least one gas source 21 and at least one flow rate controller 22. In one embodiment, the gas supply 20 is configured to supply at least one processing gas from the corresponding gas source 21 to the shower head 13 via the corresponding flow rate controller 22. Each flow rate controller 22 may include, for example, a mass flow controller or a pressure-controlled flow rate controller. Further, the gas supply 20 may include one or more flow rate modulating devices configured to modulate or pulse the flow rate of at least one processing gas.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. With this configuration, a plasma is formed from the at least one processing gas supplied to the plasma processing space 10s. Thus, the RF power supply 31 may function as at least a portion of a plasma generator configured to generate a plasma from one or more processing gases in the plasma processing chamber 10. Also, by supplying a bias RF signal to the at least one lower electrode, a bias potential is generated in the substrate W, and ion components in the formed plasma can be drawn into the substrate W.

In one embodiment, the RF power supply 31 includes a first RF generator 31a and a second RF generator 31b. The first RF generator 31a is coupled to the at least one lower electrode and/or the at least one upper electrode via the at least one impedance matching circuit, and is configured to generate a source RF signal (source RF power) for plasma generation. In one embodiment, the source RF signal has a frequency in a range of 10 MHz to 150 MHz. In one embodiment, the first RF generator 31a may be configured to generate a plurality of source RF signals having different frequencies. The generated one or more source RF signals are supplied to the at least one lower electrode and/or the at least one upper electrode.

The second RF generator 31b is coupled to the at least one lower electrode via the at least one impedance matching circuit, and is configured to generate a bias RF signal (bias RF power). The frequency of the bias RF signal may be the same as or different from the frequency of the source RF signal. In one embodiment, the bias RF signal has a frequency that is lower than the frequency of the source RF signal. In one embodiment, the bias RF signal has a frequency in a range of 100 kHz to 60 MHz. In one embodiment, the second RF generator 31b may be configured to generate a plurality of bias RF signals having different frequencies. The generated one or more bias RF signals are supplied to the at least one lower electrode. Also, in various embodiments, at least one of the source RF signal or the bias RF signal may be pulsed.

Also, the power supply 30 may include a DC power supply 32 coupled to the plasma processing chamber 10. The DC power supply 32 includes a first DC generator 32a and a second DC generator 32b. In one embodiment, the first DC generator 32a is coupled to the at least one lower electrode, and configured to generate a first DC signal. The generated first bias DC signal is applied to the at least one lower electrode. In one embodiment, the second DC generator 32b is coupled to the at least one upper electrode, and configured to generate a second DC signal. The generated second DC signal is applied to the at least one upper electrode.

In various embodiments, at least one of the first DC signal or the second DC signal may be pulsed. In this case, a sequence of voltage pulses is applied to the at least one lower electrode and/or the at least one upper electrode. The voltage pulses may have a pulse waveform that is rectangular, trapezoidal, triangular, or any combination thereof. In one embodiment, a waveform generator configured to generate a sequence of voltage pulses from the DC signal is coupled to a portion between the first DC generator 32a and the at least one lower electrode. Thus, the first DC generator 32a and the waveform generator form a voltage pulse generator. When the second DC generator 32b and the waveform generator form a voltage pulse generator, the voltage pulse generator is coupled to the at least one upper electrode. The voltage pulses may have a positive polarity or a negative polarity. Also, the sequence of voltage pulses may include, in one cycle, one or more positive voltage pulses and one or more negative voltage pulses. Note that the first DC generator 32a and the second DC generator 32b may be provided in addition to the RF power supply 31, or the first DC generator 32a may be provided instead of the second RF generator 31b.

The gas exhaust system 40 can be coupled, for example, to a gas discharge port 10e provided at the bottom of the plasma processing chamber 10. The gas exhaust system 40 may include a pressure adjusting valve and a vacuum pump. The pressure adjusting valve adjusts the internal pressure of the plasma processing space 10s. The vacuum pump may include a turbomolecular pump, a dry pump, or a combination thereof.

The controller 2 is configured to process computer-executable instructions that cause the plasma processing apparatus 1 to perform various steps described in the present disclosure. The controller 2 may be configured to control the elements of the plasma processing apparatus 1 to perform the various steps described herein. In one embodiment, a part of or the entirety of the controller 2 may be included in the plasma processing apparatus 1. The controller 2 may include a processor 2a1, a storage 2a2, and a communication interface 2a3. The controller 2 may be implemented, for example, by a computer 2a. The processor 2a1 may be configured to perform various controls by reading out a program from the storage 2a2 and executing the read-out program. This program may be previously stored in the storage 2a2 or may be acquired via a medium when necessary. The acquired program is stored in the storage 2a2, read out from the storage 2a2 by the processor 2a1, and executed. The medium may be various storage media readable by the computer 2a or may be a communication line coupled to the communication interface 2a3. The processor 2a1 may be a CPU (Central Processing Unit). The storage 2a2 may include a RAM (Random Access Memory), a ROM (Read Only Memory), an HDD (Hard Disk Drive), an SSD (Solid State Drive), or any combination thereof. The communication interface 2a3 may communicate with the plasma processing apparatus 1 via a communication line, such as a LAN (Local Area Network).

A part in the plasma processing chamber 10 (hereinafter also referred to as an “in-chamber part”) is exposed to a plasma during processing of the substrate W. Some parts are worn depending on the material, and need to be replaced.

The surface (lower surface) of the upper plate 13c is exposed to the plasma processing space 10s, and worn by exposure to a plasma. Therefore, the upper plate 13c is one of the in-chamber parts that need to be replaced after worn by a predetermined amount.

The gas diffusion chamber 13b formed in the upper support 13d communicates with the plurality of gas channels 13d1. The plurality of gas channels 13d1 communicate with the plurality of gas introducing holes 13c1 formed in the upper plate 13c. For example, when a WF₆ gas is supplied from the gas supply 20 to the shower head 13, the WF₆ gas is introduced from the gas diffusion chamber 13b into the plasma processing space 10s through the plurality of gas channels 13d1 and the plurality of gas introducing holes 13c1.

The WF₆ gas changes the color the support surface (lower surface) of the upper support 13d facing the rear surface (upper surface) of the upper plate 13c. Further, a tungsten-containing metal film of WOx or the like is attached to and deposited on the support surface of the upper support 13d. An increase in the film thickness of the deposit increases the risk of formation of particles and metal contamination in the plasma processing space 10s. The upper support 13d can be removed from the plasma processing chamber 10, followed by washing. Alternatively, the portion changed in color can be removed through abrasion. However, the washing takes a long period of time, and there is a concern about damage to the part due to abrasion. Thus, these methods are difficult to employ.

In view of this, as the cleaning method according to one embodiment, the cleaning method performed by the plasma processing apparatus 1 including the plasma processing chamber 10 and the support configured to support a part in the plasma processing chamber is provided. This cleaning method includes: (A) removing the part from the support in the plasma processing chamber 10, and transferring the part out from the plasma processing chamber; (B) attaching a protective cover to a position corresponding to an attachment position of the part; and (C) generating a plasma from a cleaning gas, and cleaning an adhered substance adhered to the support by the plasma. Here, (A) is followed by (B), and (B) is followed by (C).

### Example 1

In Example 1, the upper plate 13c including the plurality of gas introducing holes 13c1 is described as an example of the in-chamber part to be replaced. Also, taking the upper support 13d as an example of the support configured to support the in-chamber part, a plasma processing method including the cleaning method according to one embodiment will be described. In Example 1, cleaning is performed on the support surface of the upper support 13d exposed by removing the upper plate 13c at the time of replacement of the upper plate 13c.

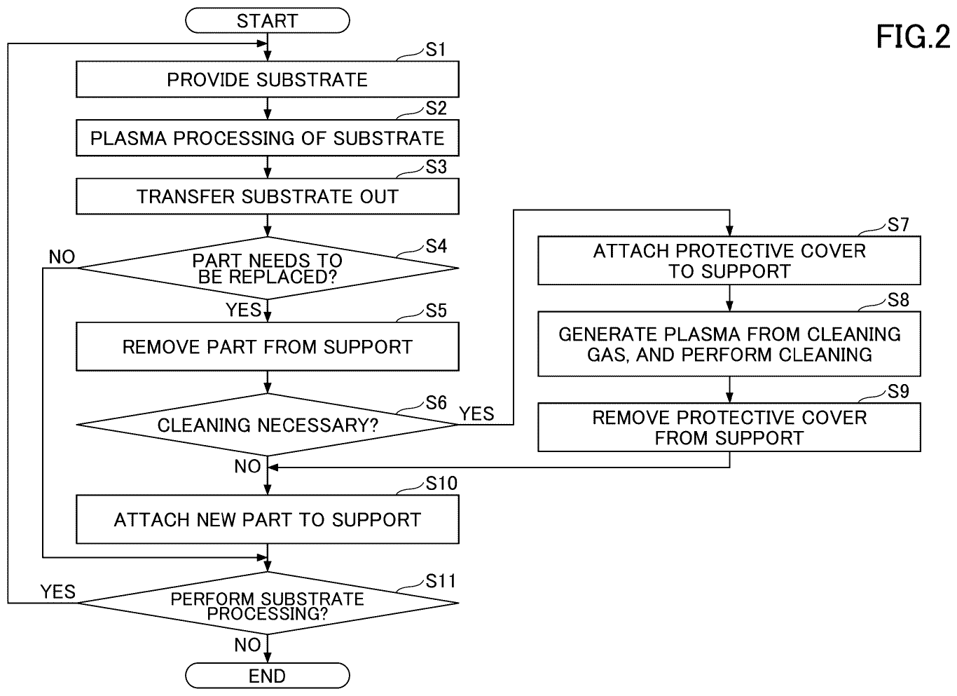

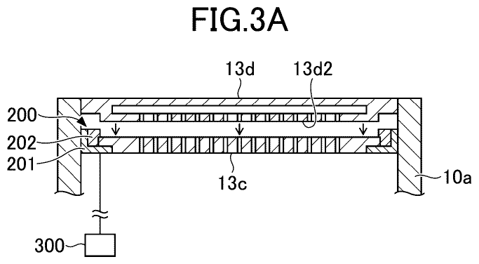

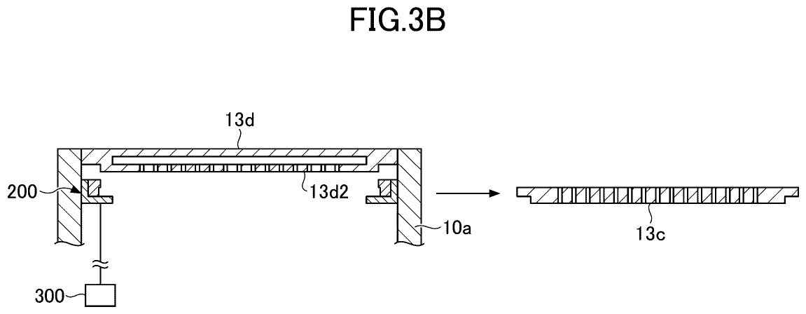

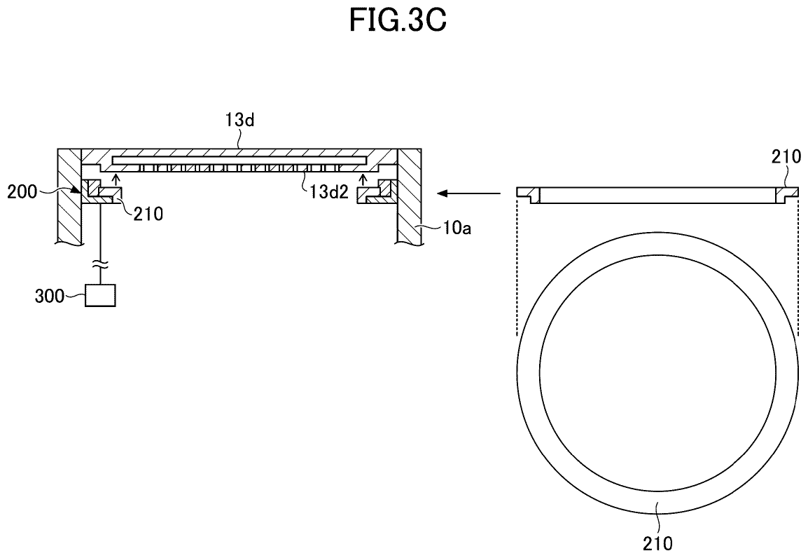

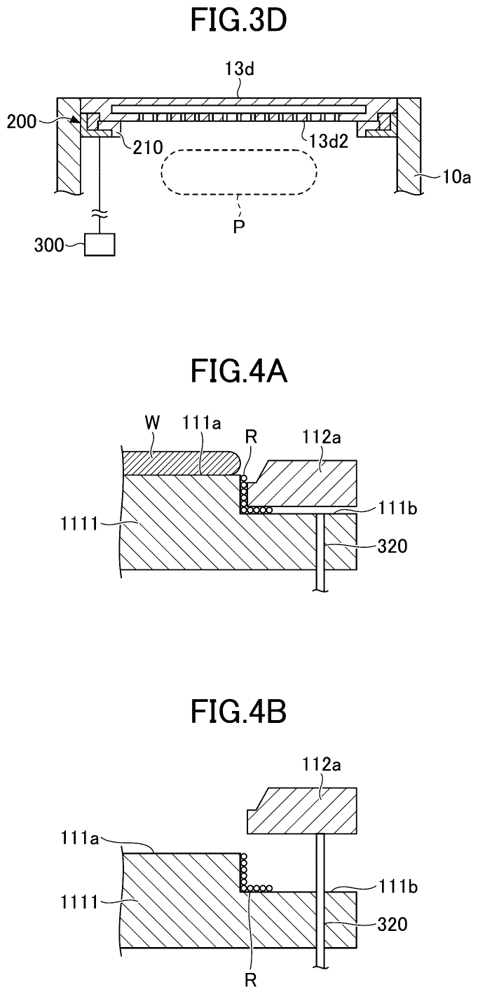

FIG. 2 is a flowchart illustrating the plasma processing method including the cleaning method according to one embodiment. FIGS. 3A to 3D are diagrams for describing Example 1 of the plasma processing method of FIG. 2. The plasma processing method according to one embodiment is controlled by the controller 2 and performed by the plasma processing apparatus 1.

When a process of FIG. 2 is started, in step S1, the substrate W is transferred into the plasma processing chamber 10 and provided to the substrate support surface 111a of the substrate support 11.

Next, in step S2, plasma processing of the substrate W is performed. In the plasma processing of the substrate W, a processing gas supplied from the gas supply 20 is introduced into the plasma processing space 10s. The RF power supply 31 supplies an RF power to the lower electrode and/or the upper electrode, thereby forming a plasma from the processing gas supplied into the plasma processing space 10s. When the processing gas is an etching gas, the substrate W is etched by the plasma. When the processing gas is a film-forming gas, a film is formed on the substrate W by the plasma.

After the plasma processing of the substrate W is performed, in step S3, the substrate W is transferred out from the plasma processing chamber 10. Next, in step S4, whether or not the in-chamber part needs to be replaced is determined. In Example 1, whether or not the upper plate 13c needs to be replaced is determined. If the upper plate 13c is worn by a predetermined amount or more, it is determined that replacement is necessary. If the amount of wearing of the upper plate 13c is less than a predetermined amount, it is determined that replacement is unnecessary.

If it is determined in step S4 that replacement of the in-chamber part is unnecessary, this is determined to be “NO”, and the process proceeds to step S11, in which whether or not to perform processing of a subsequent substrate is determined. If it is determined that there is a subsequent substrate to be processed, this is determined to be “YES”, the process returns to step S1, and the substrate processing of steps S1 to S3 is performed. If it is determined that there is not a subsequent substrate to be processed, this is determined to be “NO”, and the current process is ended.

If it is determined in step S4 that the in-chamber part needs to be replaced, this is determined to be “YES”, and the process proceeds to step S5, in which the in-chamber part is removed from the support and transferred out from the plasma processing chamber 10. For example, since the upper plate 13c worn by a predetermined amount or more needs to be replaced, the upper plate 13c is removed from the upper support 13d and transferred to the outside of the plasma processing chamber 10.

FIGS. 3A and 3B illustrate examples of transferring the upper plate 13c to the outside of the plasma processing chamber 10. The fixture 200 (the fixing portion 201 and the fastening portion 202) is provided on the inner wall surface of the side wall 10a of the plasma processing chamber 10, and is configured to be vertically movable by a raising and lowering portion 300. When the fastening portion 202 screws the upper plate 13c to the upper support 13d, the screw is removed at the time of transferring the upper plate 13c out, and the fixture 200 is lowered by the raising and lowering portion 300. By this, the upper plate 13c is lowered as illustrated in FIG. 3A, and the upper plate 13c is delivered onto a pin (not shown).

In a state in which the upper plate 13c is held by the pin, an arm of a transfer device (not shown) disposed outside the plasma processing chamber 10 is inserted into the plasma processing chamber 10, and the pin is lowered to cause the arm to hold the upper plate 13c. Then, by retracting the arm from the plasma processing chamber 10, the upper plate 13c is automatically transferred to the outside of the plasma processing chamber 10 as illustrated in FIG. 3B.

As illustrated in FIG. 2, next, in step S6, whether or not the support configured to support the in-chamber part needs to be cleaned is determined. If the thickness of the deposit adhered to the support surface 13d2 (lower surface) of the upper support 13d is equal to or greater than a predetermined thickness, it may be determined that cleaning is necessary. The thickness of the deposit can be measured by an optical technique. Also, the support surface 13d2 (lower surface) of the upper support 13d exposed when the upper plate 13c is removed may be visually checked, and whether or not cleaning is necessary may be determined in accordance with the extent of stain or color change. Further, when a cumulative time of supply of the RF power into the plasma processing chamber 10 after attachment of the new upper plate 13c is equal to or greater than a predetermined time, it may be determined that cleaning is necessary.

If it is determined in step S6 that cleaning is unnecessary, this is determined to be “NO”, and the process proceeds to step S10, in which the new upper plate 13c is attached to the upper support 13d. For example, the new upper plate 13c is held by the arm of the transfer device, the arm is inserted into the plasma processing chamber 10, and the new upper plate 13c is delivered onto a pin (not shown). The pin is lowered to dispose the outer circumferential portion of the new upper plate 13c on the fixture 200. The fixture 200 is raised by the raising and lowering portion 300. Thus, the upper plate 13c is raised and supported by the upper support 13d. When the upper plate 13c is screwed to the upper support 13d, the screws are fastened. Subsequently, the process proceeds to step S11. Note that the new upper plate 13c is not limited to the upper plate 13c that has never been used, and includes the upper plate 13c that has been restored to a level of an upper plate that has never been used.

When it is determined in step S6 that cleaning is necessary, this is determined to be “YES”, and the process proceeds to step S7, in which a protective cover is attached to the support. For example, FIG. 3C illustrates an example of a longitudinal cross section and an upper surface of a protective cover 210. The protective cover 210 is different from the in-chamber part in shape. The upper plate 13c includes an outer edge portion and a central portion inward of the outer edge portion. The outer edge portion of the upper plate 13c is a portion to be fixed by the fixture 200. Note that the gas introducing holes 13c1 are provided in the central portion of the upper plate 13c. In Example 1, the protective cover 210 has a shape in which a portion (the central portion) of the upper plate 13c other than the outer edge portion is hollowed out (removed) in a circular shape. That is, the protective cover 210 is an annular member, and has a shape identical to that of the outer edge portion of the upper plate 13c. However, the shape of the protective cover 210 is not limited to this, and may be any shape as long as cleaning can be performed in a state in which the support surface 13d2 of the upper support 13d is exposed and the deposit on the support surface 13d2 can be readily removed.

An inner diameter of the protective cover 210 is greater than a distance from the center of the upper plate 13c to the circumferentially outermost gas introducing hole 13c1 of the plurality of gas introducing holes 13c1. Thus, the plurality of gas introducing holes 13c1 of the support surface 13d2 can be directly cleaned. The protective cover 210 may be formed of the same material as that of the upper plate 13c, or may be formed of a material different from that of the upper plate 13c. For example, the protective cover 210 may be formed of silicon or quartz. However, this is by no means a limitation. The protective cover 210 may be formed of a plasma-resistant material capable of protecting an O-ring, a screw, or the like included in the fastening portion 202 of the fixture 200.

Attachment of the protective cover 210 in step S7 will be described with reference to FIG. 3C. The transfer device causes the arm to hold the protective cover 210, inserts the arm into the plasma processing chamber 10, and delivers the protective cover 210 onto a pin (not shown). The pin is lowered to dispose the protective cover 210 on the fixture 200, and the fixture 200 and the protective cover 210 are raised by the raising and lowering portion 300. Thus, the protective cover 210 is supported by the upper support 13d. When the upper plate 13c is screwed to the upper support 13d, the protective cover 210 is screwed to the upper support 13d.

As illustrated in FIG. 3D, the protective cover 210 covers the fixture 200 configured to fix the upper plate 13c to the upper support 13d. Thus, an O-ring, a screw, or the like included in the fixture 200 can be protected from a plasma during cleaning.

After attachment of the protective cover 210, in step S8 of FIG. 2, a cleaning gas is supplied into the plasma processing chamber 10, followed by supply of an RF power, thereby generating a plasma from the cleaning gas. The interior of the plasma processing chamber 10 is cleaned by the generated plasma. At this time, as illustrated in FIG. 3D, plasma processing is performed in a state in which the upper plate 13c is removed. Therefore, the support surface 13d2 of the upper support 13d is exposed to a plasma P, and the support surface 13d2 of the upper support 13d can be directly cleaned by the plasma P. Thus, compared to removing the upper support 13d for washing or physically abrading the upper support 13d, the deposit on the support surface 13d2 of the upper support 13d can be removed in a relatively short time while suppressing damage to the upper support 13d.

Also, as illustrated in FIG. 3D, the protective cover 210 can prevent degradation in the O-ring and the screw of the fixture 200 during cleaning. Also, in Example 1, cleaning is performed in a state of directly exposing the support surface 13d2 of the upper support 13d to the plasma. This can directly clean a deposit that cannot be removed unless the upper plate 13c is removed, such as the deposit accumulated on the support surface 13d2 of the upper support 13d corresponding to the ends of the upper plate 13c or the gas introducing holes 13c1. As a result, it is possible to enhance cleaning efficiency of the upper support 13d.

When a tungsten-containing metal film of WFx or the like adheres to the support surface 13d2 of the upper support 13d, an O₂ gas and a CF₄ gas may be used as the cleaning gas. The tungsten-containing metal film of WFx or the like deposited on the support surface 13d2 of the upper support 13d reacts with radicals of the CF₄ gas to form a WFx gas, which volatilizes to enable removal of the deposit of the metal film.

The above gas is an example of the cleaning gas, and optimal conditions for cleaning, such as a cleaning gas and the like, may vary depending on the components of the deposit adhered to the support surface 13d2. For example, when an organic film containing C and F adheres to the support surface 13d2 of the upper support 13d, an O₂ gas may be used as the cleaning gas.

After cleaning, in step S9 of FIG. 2, the protective cover 210 is removed from the support, and transferred to the outside of the plasma processing chamber 10 using a transfer device. A method of removing and transferring the protective cover 210 is the same as the method of removing and transferring the upper plate 13c described in step S5. Therefore, description of the method of removing and transferring the protective cover 210 is omitted here.

After transferring the protective cover 210 out, in step S10, a new in-chamber part is transferred into the plasma processing chamber 10 using a transfer device and then attached. In Example 1, the new upper plate 13c is transferred into the plasma processing chamber 10 and attached to the upper support 13d. A method of transferring and attaching the new upper plate 13c is the same as the method of transferring and attaching the protective cover 210 described in step S7. Therefore, description of the method of transferring and attaching the new upper plate 13c is omitted here.

Next, in step S11, whether or not to perform subsequent substrate processing is determined. If it is determined that there is a subsequent substrate to be processed, the process returns to step S1, and the substrate processing of steps S1 to S3 is performed. If it is determined that there is not a subsequent substrate to be processed, the current process is ended.

### Example 2

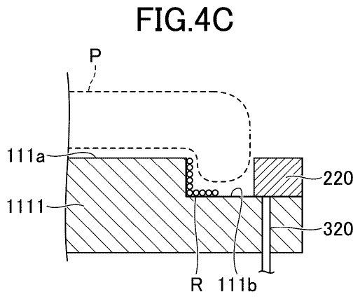

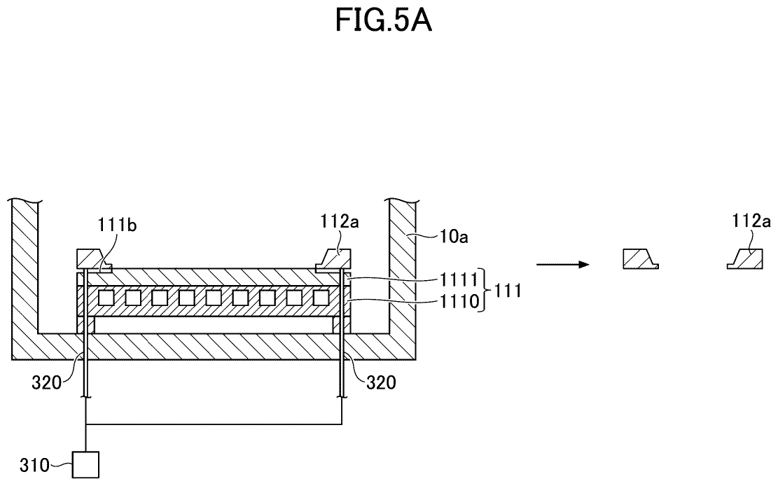

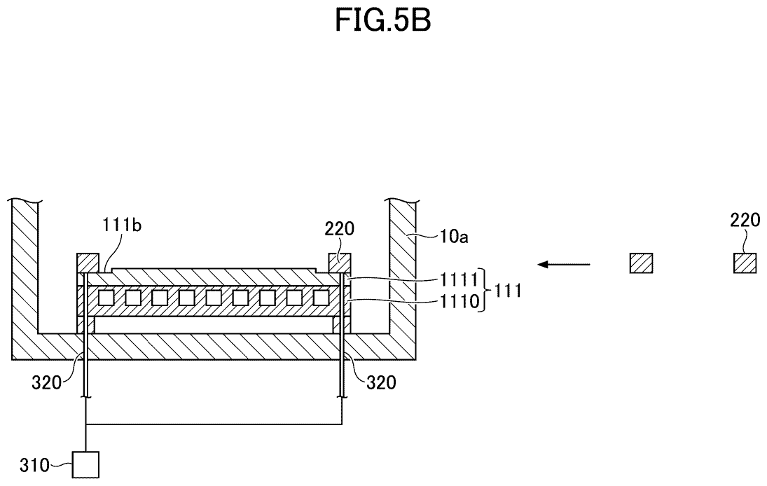

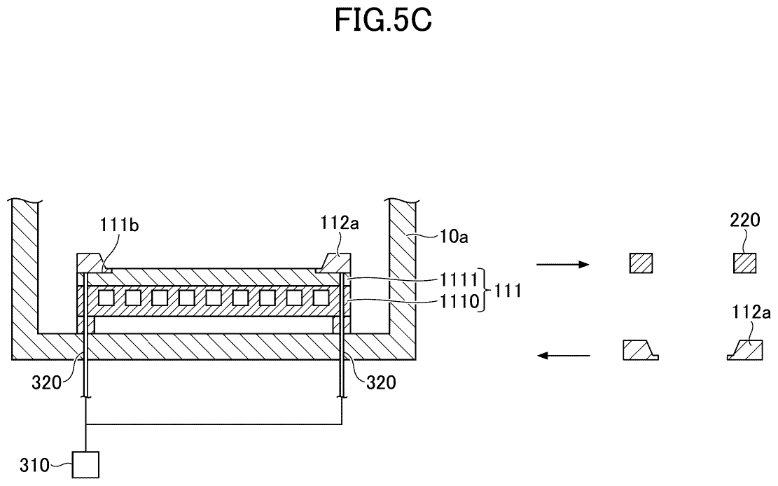

In Example 2, an edge ring 112a disposed to enclose the substrate W is described as an example of the in-chamber part to be replaced. Also, taking the substrate support 11 as an example of the support configured to support the in-chamber part, a plasma processing method including the cleaning method according to one embodiment will be described. In Example 2, cleaning is performed on the shoulder portion of the electrostatic chuck 1111 and the ring support surface 111b of the substrate support 11, which are exposed by removing the edge ring 112a at the time of replacement of the edge ring 112a. FIGS. 4A to 4C and FIGS. 5A to 5C are diagrams for describing Example 2 of the plasma processing method of FIG. 2. FIGS. 4A to 4C are enlarged diagrams of the circumference of the edge ring 112a.

When the process of steps S1 to S3 of FIG. 2 is performed, as illustrated in FIG. 4A, a reaction product formed during the plasma processing of the substrate W enters and adheres to the gap between the electrostatic chuck 1111 and the edge ring 112a. As a result, a deposit R is deposited on the shoulder portion (side surface) of the electrostatic chuck 1111 and the ring support surface 111b. Although the edge ring 112a is placed on the ring support surface 111b, illustration of the gap is emphasized in FIG. 4A.

When it is determined in step S4 of FIG. 2 that the edge ring 112a, which is an example of the in-chamber part, needs to be replaced, the process proceeds to step S5, in which the edge ring 112a is removed from the substrate support 11, which is an example of the support. The removed edge ring 112a is transferred out from the plasma processing chamber 10. For example, as illustrated in FIGS. 4B and 5A, the edge ring 112a that is worn by a predetermined amount or more is raised by a pin 320 penetrating through the electrostatic chuck 1111 of the substrate support 11. In this state, an arm of a transfer device (not shown) is inserted into the plasma processing chamber 10, and the edge ring 112a is delivered from the pin 320 to the arm. Then, by retracting the arm from the plasma processing chamber 10, the edge ring 112a is automatically transferred to the outside of the plasma processing chamber 10.

Next, whether or not cleaning is necessary is determined in step S6 of FIG. 2. If it is determined that the shoulder portion of the electrostatic chuck 1111 or the ring support surface 111b of the substrate support 11 needs to be cleaned, the process proceeds to step S7. A method of determining whether or not the ring support surface 111b needs to be cleaned may be the same as that used in Example 1.

If it is determined in step S6 that cleaning is unnecessary, the process proceeds to step S10, in which the new edge ring 112a is attached to the ring support surface 111b of the substrate support 11. For example, the new edge ring 112a is held by the arm of the transfer device, the arm is inserted into the plasma processing chamber 10, and the new edge ring 112a is delivered onto the pin 320. The pin 320 is lowered to dispose the new edge ring 112a on the ring support surface 111b. Subsequently, the process proceeds to step S11.

If it is determined in step S6 that cleaning is necessary, the process proceeds to step S7, in which a protective cover is attached to the substrate support 11. For example, FIG. 4C illustrates an example of a longitudinal cross section of a protective cover 220. The protective cover 220 is different from the in-chamber part in shape. In Example 2, the protective cover 220 has a shape in which an inner circumferential portion of the edge ring 112a is removed. That is, the protective cover 220 is an annular member, and has the same shape as that of an outer circumferential portion of the edge ring 112a. Thus, the protective cover 220 is an annular member having a width smaller than that of the edge ring 112a in a top view. However, the shape of the protective cover 220 is not limited to this, and may be any shape as long as cleaning can be performed in a state in which a circumferentially inner portion of the ring support surface 111b is exposed and the deposit R on the shoulder portion of the electrostatic chuck 1111 and the ring support surface 111b can be readily removed.

An inner diameter of the protective cover 220 is greater than the inner diameter of the edge ring 112a. The protective cover 220 may be formed of the same material as that of the edge ring 112a, or may be formed of a material different from that of the edge ring 112a. For example, the protective cover 220 may be formed of silicon or quartz. However, this is by no means a limitation. The protective cover 220 may be formed of a plasma-resistant material.

Attachment of the protective cover 220 in step S7 will be described with reference to FIGS. 4C and 5B. The transfer device causes the arm to hold the protective cover 220, inserts the arm into the plasma processing chamber 10, and delivers the protective cover 220 onto the pin 320. The pin 320 is lowered by a raising and lowering portion 310 configured to be vertically movable, thereby disposing the protective cover 220 on the ring support surface 111b.

When the protective cover 220 is disposed on the ring support surface 111b, the protective cover 220 covers the pin 320. In this state, in step S8 of FIG. 2, a cleaning gas is supplied into the plasma processing chamber 10, followed by supply of an RF power, thereby generating a plasma from the cleaning gas. The interior of the plasma processing chamber 10 is cleaned by the generated plasma. At this time, plasma processing is performed in a state in which the edge ring 112a is removed. Therefore, as illustrated in FIG. 4C, the circumferentially inner portion of the ring support surface 111b and the shoulder portion of the electrostatic chuck 1111 are exposed to the plasma P, and the circumferentially inner portion of the ring support surface 111b and the shoulder portion of the electrostatic chuck 1111 can be directly cleaned by the plasma P. Also, the protective cover 220 covers the pin 320 and a circumferentially outer portion of the ring support surface 111b having a relatively small amount of a deposit. Thus, the deposit R on the circumferentially inner portion of the ring support surface 111b and the shoulder portion of the electrostatic chuck 1111 can be removed in a relatively short time while suppressing damage to the circumferentially outer portion of the ring support surface 111b, the pin 320, and the hole of the pin 320.

After cleaning, in step S9 of FIG. 2, the protective cover 220 is removed from the substrate support 11, and in step S10, the new edge ring 112a is disposed on the substrate support 11. Note that the new edge ring 112a is not limited to the edge ring 112a that has never been used, and includes the edge ring 112a that has been restored to a level of an edge ring that has never been used.

Thus, as illustrated in FIG. 5C, the protective cover 220 is removed from the substrate support 11, and transferred to the outside of the plasma processing chamber 10 using the transfer device. Also, the new edge ring 112a is transferred into the plasma processing chamber 10 using the transfer device, and placed on the ring support surface 111b.

Next, in step S11, whether or not to perform subsequent substrate processing is determined. If it is determined that there is a subsequent substrate to be processed, the process returns to step S1, and the substrate processing of steps S1 to S3 is performed. If it is determined that there is not a subsequent substrate to be processed, the current process is ended.

### Effects

According to the cleaning method according to one embodiment, the cleaning efficiency of the in-chamber part can be enhanced. For example, according to Example 1, the cleaning efficiency of the upper support 13d can be enhanced. According to Example 2, the cleaning efficiency of the substrate support 11 and the shoulder portion of the electrostatic chuck 1111 can be enhanced.

Also, in Example 1, the protective cover 210 can protect the fastening portion 202 from damage to the fastening portion 202 caused by entry of a plasma from the inner circumferential side of the fixture 200. Also, in Example 2, the protective cover 220 can protect the outer circumferential portion of the ring support surface 111b, the pin 320, and the hole of the pin 320 from damage to the outer circumferential portion of the ring support surface 111b, the pin 320, and the hole of the pin 320.

### Modified Example

In the above-described Examples 1 and 2, the cleaning method is performed at the time of replacement of the in-chamber part. However, this is by no means a limitation. The cleaning method according to the present embodiment may be performed at any timing other than the timing of replacing the upper plate 13c or the edge ring 112a.

Further, in Examples 1 and 2, the deposit of a metal-containing substance is cleaned. However, the deposit (adhered substance) to be cleaned may contain at least one of the metal-containing substance or an organic substance.

The plasma processing apparatus 1 may be an etching apparatus or a film forming apparatus. For example, the plasma processing apparatus 1 may be a CVD (chemical vapor deposition) apparatus or an ALD (atomic layer deposition) apparatus.

The transfer of the in-chamber part (the upper plate 13c or the edge ring 112a) and the protective covers 210 and 220 is not limited to automatic transfer, and may be performed manually.

The embodiments disclosed above include, for example, the following.

### Clause 1

A cleaning method performed by a plasma processing apparatus including a plasma processing chamber and a support configured to support a part in the plasma processing chamber, the cleaning method including:
(A) removing the part from the support in the plasma processing chamber, and transferring the part out from the plasma processing chamber;
(B) attaching a protective cover to a position corresponding to an attachment position of the part; and
(C) generating a plasma from a cleaning gas, and cleaning an adhered substance adhered to the support by the plasma, wherein
(A) is followed by (B), and (B) is followed by (C).

### Clause 2

The cleaning method according to clause 1, wherein
the protective cover is different from the part in shape.

### Clause 3

The cleaning method according to clause 1 or 2, wherein
the protective cover is formed of silicon or quartz.

### Clause 4

The cleaning method according to any one of clauses 1 to 3, wherein
the part is an upper plate including a plurality of gas introducing holes.

### Clause 5

The cleaning method according to clause 4, wherein
the protective cover is an annular member and has a shape in which a central portion of the upper plate is hollowed out, and
the shape of the protective cover is identical to a shape of an outer edge portion of the upper plate.

### Clause 6

The cleaning method according to clause 4 or 5, wherein
an inner diameter of the protective cover is greater than a distance from a center of the upper plate to a circumferentially outermost gas introducing hole of the plurality of gas introducing holes.

### Clause 7

The cleaning method according to any one of clauses 4 to 6, wherein
the protective cover covers a fixture configured to fix the upper plate to the support.

### Clause 8

The cleaning method according to any one of clauses 1 to 3, wherein
the part is an edge ring disposed to enclose a substrate.

### Clause 9

The cleaning method according to clause 8, wherein
the protective cover is an annular member and has a shape in which a central portion of the edge ring is hollowed out, and
the shape of the protective cover is identical to a shape of an outer circumferential portion of the edge ring.

### Clause 10

The cleaning method according to clause 8 or 9, wherein
an inner diameter of the protective cover is greater than an inner diameter of the edge ring.

### Clause 11

The cleaning method according to any one of clauses 8 to 10, wherein
the protective cover covers a pin configured to place the edge ring at the support.

### Clause 12

The cleaning method according to any one of clauses 1 to 11, wherein
the adhered substance includes at least one of a metal-containing substance or an organic substance.

### Clause 13

The cleaning method according to any one of clauses 1 to 12, wherein
in (A), the part is transferred out from the plasma processing chamber using a transfer device.

### Clause 14

The cleaning method according to any one of clauses 1 to 13, wherein
in (B), the protective cover is transferred into the plasma processing chamber using a transfer device.

### Clause 15

The cleaning method according to any one of clauses 1 to 14, wherein
after (B), the protective cover is transferred out from the plasma processing chamber using a transfer device.

### Clause 16

The cleaning method according to any one of clauses 1 to 15, wherein
after the protective cover is transferred out, the part that is new is transferred into the plasma processing chamber using a transfer device.

### Clause 17

The cleaning method according to any one of clauses 1 to 16, wherein
the cleaning method is performed at a time of replacement of the part.

### Clause 18

A plasma processing apparatus, including:
a plasma processing chamber;
a support configured to support a part in the plasma processing chamber; and
a controller including a memory and a processor coupled to the memory, wherein
the controller is configured to control:
   (A) removing the part from the support in the plasma processing chamber, and transferring the part out from the plasma processing chamber,
   (B) attaching a protective cover to a position corresponding to an attachment position of the part, and
   (C) generating a plasma from a cleaning gas, and cleaning an adhered substance adhered to the support by the plasma, and
(A) is followed by (B), and (B) is followed by (C).

Note that the present disclosure is not limited to the configurations described herein, and, for example, it is possible to combine other elements with the configurations described in the above embodiments and examples. In this regard, modifications are possible without departing from the intent of the present disclosure, and can be appropriately defined in accordance with applied forms. Also, the matters described in a plurality of examples can have any other configuration as long as there is no contradiction, and can be combined as long as there is no contradiction.

For example, Example 1 and Example 2 can be combined and performed simultaneously. Thus, cleaning of a plurality of in-chamber parts can be performed efficiently.

According to one aspect of the present disclosure, it is possible to enhance cleaning efficiency of a part in a chamber.

What is claimed is:

1. A cleaning method performed by a plasma processing apparatus including a plasma processing chamber and a support configured to support a part in the plasma processing chamber, the cleaning method comprising:
(A) removing the part from the support in the plasma processing chamber, and transferring the part out from the plasma processing chamber;
(B) attaching a protective cover to a position corresponding to an attachment position of the part; and
(C) generating a plasma from a cleaning gas, and cleaning an adhered substance adhered to the support by the plasma, wherein
(A) is followed by (B), and (B) is followed by (C).

2. The cleaning method according to claim 1, wherein
the protective cover is different from the part in shape.

3. The cleaning method according to claim 1, wherein
the protective cover is formed of silicon or quartz.

4. The cleaning method according to claim 1, wherein
the part is an upper plate including a plurality of gas introducing holes.

5. The cleaning method according to claim 4, wherein
the protective cover is an annular member and has a shape in which a portion of the upper plate other than an outer edge portion is hollowed out, and
the shape of the protective cover is identical to a shape of the outer edge portion.

6. The cleaning method according to claim 4, wherein
an inner diameter of the protective cover is greater than a distance from a center of the upper plate to a circumferentially outermost gas introducing hole of the plurality of gas introducing holes.

7. The cleaning method according to claim 4, wherein
the protective cover covers a fixture configured to fix the upper plate to the support.

8. The cleaning method according to claim 1, wherein
the part is an edge ring disposed to enclose a substrate.

9. The cleaning method according to claim 8, wherein
the protective cover is an annular member and has a shape in which an inner circumferential portion of the edge ring is removed, and
the shape of the protective cover is identical to a shape of an outer circumferential portion of the edge ring.

10. The cleaning method according to claim 8, wherein
an inner diameter of the protective cover is greater than an inner diameter of the edge ring.

11. The cleaning method according to claim 8, wherein
the protective cover covers a pin configured to place the edge ring at the support.

12. The cleaning method according to claim 1, wherein
the adhered substance includes at least one of a metal-containing substance or an organic substance.

13. The cleaning method according to claim 1, wherein
in (A), the part is transferred out from the plasma processing chamber using a transfer device.

14. The cleaning method according to claim 1, wherein
in (B), the protective cover is transferred into the plasma processing chamber using a transfer device.

15. The cleaning method according to claim 1, wherein
after (B), the protective cover is transferred out from the plasma processing chamber using a transfer device.

16. The cleaning method according to claim 1, wherein
after the protective cover is transferred out, the part that is new is transferred into the plasma processing chamber using a transfer device.

17. The cleaning method according to claim 1, wherein
the cleaning method is performed at a time of replacement of the part.

18. A plasma processing apparatus, comprising:
a plasma processing chamber;
a support configured to support a part in the plasma processing chamber; and
a controller including a memory and a processor coupled to the memory, wherein
the controller is configured to control:
(A) removing the part from the support in the plasma processing chamber, and transferring the part out from the plasma processing chamber,
(B) attaching a protective cover to a position corresponding to an attachment position of the part, and
(C) generating a plasma from a cleaning gas, and cleaning an adhered substance adhered to the support by the plasma, and
(A) is followed by (B), and (B) is followed by (C).
